(19) United States
(12) Patent Application Publication
(10) Pub. No.: US 2026/0247716 A1
(43) Pub. Date: Aug. 20, 2026

(54) ARRAY SUBSTRATE, AND DISPLAY PANEL

(71) Applicants: Ordos Yuansheng Optoelectronics Co., Ltd., Inner Mongolia (CN); BOE TECHNOLOGY GROUP CO., LTD., Beijing (CN)

(72) Inventors: Jianyun XIE, Beijing (CN); Zhiming LI, Beijing (CN); Chao LIANG, Beijing (CN); Jingyi XU, Beijing (CN); Peirong HUO, Beijing (CN); Jing LIU, Beijing (CN); Biqi LI, Beijing (CN)

(73) Assignees: Ordos Yuansheng Optoelectronics Co., Ltd., Inner Mongolia (CN); BOE TECHNOLOGY GROUP CO., LTD., Beijing (CN)

(21) Appl. No.: 18/876,653

(22) PCT Filed: Jun. 20, 2022
(86) PCT No.: PCT/CN2022/099916

§ 371 Date: Dec. 18, 2024

(51) Int. Cl. H10D 86/40; G02F 1/1362; G02F 1/1368; H10D 86/60

(52) U.S. Cl. CPC H10D 86/443; G02F 1/136209; G02F 1/13624; G02F 1/13629; G02F 1/1368; H10D 86/60

(57) ABSTRACT

An array substrate and a display panel including the same are disclosed. The array substrate includes a plurality of scanning lines and a plurality of data lines. The plurality of data lines are intersected with the plurality of scanning lines to define a plurality of sub-pixel areas. The scanning line includes a plurality of sub-scanning lines spaced apart from each other and a connection line connecting two adjacent sub-scanning lines. The array substrate further includes a base substrate and a plurality of conductive layers provided on a side of the base substrate, and the sub-scanning line and the connection line are arranged in different conductive layers respectively.

### CROSS-REFERENCE TO RELATED APPLICATIONS

The present application is the U.S. National Stage of International Application No. PCT/CN2022/099916 filed on Jun. 20, 2022, the entire contents of which are incorporated herein by reference for all purposes.

### TECHNICAL FIELD

The present disclosure relates to the field of display technology, and specifically, to an array substrate and a display panel, and a display device.

### BACKGROUND

In the manufacturing process of liquid crystal panel, an exposed, long and straight metal line is like an antenna and thus has an antenna effect, therefore in the manufacturing process, the metal line will collect charge continually, which leads to a high potential of the metal line. The longer the metal line, the more the collected charge, and the higher the potential is.

With the continuous development of display technology, the design of liquid crystal panel gradually tends to a refined structure and a large screen. As the size of the liquid crystal panel increases continuously, the size of the metal wire increases continuously, and the antenna effect leads to a significant increase in the defective rate of the display panel. Therefore, the antenna effect of the display panel needs to be avoided.

It is to be understood that the above information disclosed in the Background section is only for enhancement of understanding of the background of the present disclosure and therefore it may contain information that does not form the prior art that is already known to a person skilled in the art.

### SUMMARY

An object of the present disclosure is to provide an array substrate and a display panel, and a display device.

In order to achieve the above objective, the present disclosure provides the following technical solutions.

A first aspect of the present disclosure provides an array substrate including a plurality of scanning lines and a plurality of data lines, wherein
the plurality of data lines are intersected with the plurality of scanning lines to define a plurality of sub-pixel areas;
the scanning line includes a plurality of sub-scanning lines spaced apart from each other and a connection line connecting two adjacent sub-scanning lines; and
the array substrate further includes a base substrate and a plurality of conductive layers provided on a side of the base substrate, and the sub-scanning line and the connection line are arranged in different conductive layers respectively.

In an embodiment of the present disclosure, the array substrate further includes a plurality of transistors, and
the plurality of conductive layers include:
a first conductive layer, provided on the side of the base substrate, and including a gate electrode of the transistor; and
a second conductive layer, provided on a side, away from the base substrate, of the first conductive layer, and including a source electrode and a drain electrode of the transistor,
wherein the connection line is arranged in the second conductive layer and the sub-scanning line is arranged in the first conductive layer.

In an embodiment of the present disclosure, the plurality of conductive layers further include:
a third conductive layer, provided between the base substrate and the first
conductive layer, and including a light-shielding structure.

In an embodiment of the present disclosure, the array substrate further includes
a plurality of transistors, and
the plurality of conductive layers include:
a first conductive layer, provided on the side of the base substrate, and including a gate electrode of the transistor;
a second conductive layer, provided on a side, away from the base substrate, of the first conductive layer, and including a source electrode and a drain electrode of the transistor; and
a third conductive layer, provided between the base substrate and the first conductive layer, and including a light-shielding structure,
wherein the connection line is arranged in the third conductive layer and the sub-scanning line is arranged in the first conductive layer.

In an embodiment of the present disclosure, the array substrate further includes a plurality of transistor,
the plurality of conductive layers include:
a first conductive layer, provided on the side of the base substrate, and including a gate electrode of the transistor;
a second conductive layer, provided on a side, away from the base substrate, of the first conductive layer, and including a source electrode and a drain electrode of the transistor;
a third conductive layer, provided between the base substrate and the first conductive layer, and including a light-shielding structure; and
a fourth conductive layer, provided on a side, close to the base substrate, of the third conductive layer, or between the third conductive layer and the first conductive layer, or between the first conductive layer and the second conductive layer, or on a side, away from the base substrate, of the second conductive layer,
wherein the connection line is arranged in the fourth conductive layer and the sub-scanning line is arranged in the first conductive layer.

In an embodiment of the present disclosure, the scanning line extends in a first direction, the sub-scanning lines are arranged in the first direction, the sub-scanning line has a head end and a tail end, and the tail end of a previous sub-scanning line is connected to the head end of a next the sub-scanning line by the connection line; and
an orthographic projection, on the base substrate, of the connection line connecting the two adjacent sub-scanning lines is at least partially overlapped with orthographic projections, on the base substrate, of the two adjacent sub-scanning lines.

In an embodiment of the present disclosure, a second sub-scanning line of the two adjacent sub-scanning lines is provided at a side, away from the head end of a first sub-scanning line of the two adjacent sub-scanning lines in the first direction, of the tail end of the first sub-scanning line.

In an embodiment of the present disclosure, as for the two adjacent sub-scanning lines, an interval between the tail end of the first sub-scanning line and the head end of the second the sub-scanning line is not less than 3 μm.

In an embodiment of the present disclosure, the array substrate further includes an active layer, a first gate insulating layer and an interlayer dielectric layer, the active layer is provided between the base substrate and the first conductive layer, the first gate insulating layer is provided between the active layer and the first conductive layer, and the interlayer dielectric layer is provided between the first conductive layer and the second conductive layer;

when the connection line is arranged in the second conductive layer, the interlayer dielectric layer is provided with a first through-hole passing through the interlayer dielectric layer, and an orthographic projection, on the base substrate, of the first through-hole is at least partially overlapped with the orthographic projection, on the base substrate, of the sub-scanning line, and is at least partially overlapped with the orthographic projection, on the base substrate, of the connection line; and

the connection line is connected to the sub-scanning line through the first through-hole, and the first through-hole has an aperture of not less than 3 μm.

In an embodiment of the present disclosure, the plurality of conductive layers further include the third conductive layer, the array substrate further includes a buffer layer and a first gate insulating layer, and the buffer layer and the first gate insulating layer are stacked between the third conductive layer and the first conductive layer in a direction away from the base substrate;

when the connection line is arranged in the third conductive layer, the buffer layer and the first gate insulating layer are provided with a first through-hole passing through the buffer layer and the first gate insulating layer, and an orthographic projection, on the base substrate, of the first through-hole is at least partially overlapped with the orthographic projection, on the base substrate, of the sub-scanning line, and is at least partially overlapped with the orthographic projection, on the base substrate, of the connection line; and
the connection line is connected to the sub-scanning line through the first through-hole, and the first through-hole has an aperture of not less than 3 μm.

In an embodiment of the present disclosure, the first through-hole includes a head end through-hole and a tail end through-hole, the tail end through-hole is provided at the tail end of the first sub-scanning line of the two adjacent sub-scanning lines, and the head end through-hole is provided at the head end of the second sub-scanning line of the two adjacent scanning lines;
an interval, in the first direction, between an edge of the tail end through-hole and an end surface of the tail end of the first sub-scanning line of the two adjacent sub-scanning lines is not less than 2.1 μm; and
an interval, in the first direction, between an edge of the head end through-hole and an end surface of the head end of the second sub-scanning line of the two adjacent sub-scanning lines is not less than 2.1 μm.

In an embodiment of the present disclosure, the orthographic projection, on the base substrate, of the first through-hole is located within the orthographic projection, on the base substrate, of the connection line;
an interval, in the first direction, between the edge of the tail end through-hole and an end surface of the connection line is not less than 2.1 μm; and
an interval, in the first direction, between the edge of the head end through-hole and the end surface of the connection line is not less than 2.1 μm.

In an embodiment of the present disclosure, the data line is arranged in the second conductive layer; and
an interval, in the first direction, between the data line and the drain electrode of the transistor is not less than 2.9 μm, an interval, in the first direction, between the drain electrode of the transistor and the connection line is not less than 3 μm, and an interval, in the first direction, between the connection line and the data line is not less than 3 μm.

In an embodiment of the present disclosure, the first gate insulating layer and the interlayer dielectric layer are provided with a second through-hole passing through the first gate insulating layer and the interlayer dielectric layer, the source electrode and the drain electrode of the transistor in the second conductive layer are connected to the active layer through the second through-hole, and the second through-hole has an aperture of not less than 2.8 μm.

In an embodiment of the present disclosure, the sub-scanning line further includes an intermediate portion between the head end and the tail end; and
as for the two adjacent sub-scanning lines, the intermediate portion of the second sub-scanning line is provided at a side, away from the head end of the first sub-scanning line in the first direction, of the tail end of the first sub-scanning line, and the head end of the second sub-scanning line is provided at a side, in a second direction, of the tail end of the first sub-scanning line, the second direction being perpendicular to the first direction.

In an embodiment of the present disclosure, a first gap is provided between the two adjacent sub-scanning lines in the first direction, and the first gap has a dimension of not less than 2.4 μm in the first direction.

In an embodiment of the present disclosure, the array substrate further includes an active layer, a first gate insulating layer and an interlayer dielectric layer, the active layer is provided between the base substrate and the first conductive layer, the first gate insulating layer is provided between the active layer and the first conductive layer, and the interlayer dielectric layer is provided between the first conductive layer and the second conductive layer;
the connection line is arranged in the second conductive layer, the interlayer dielectric layer is provided with a first through-hole passing through the interlayer dielectric layer, an orthographic projection, on the base substrate, of the first through-hole is at least partially overlapped with the orthographic projection, on the base substrate, of the sub-scanning line; and
the connection line is connected to the sub-scanning line through the first through-hole, and the first through-hole has an aperture of not less than 3 μm.

In an embodiment of the present disclosure, when the plurality of conductive layers further include the third conductive layer, the array substrate further includes a buffer layer and a first gate insulating layer, and the buffer layer and the first gate insulating layer are stacked between the third conductive layer and the first conductive layer in a direction away from the base substrate;
the connection line is arranged in the third conductive layer, the buffer layer and the first gate insulating layer are provided with a first through-hole passing through the buffer layer and the first gate insulating layer, and an orthographic projection, on the base substrate, of the first through-hole is at least partially overlapped with the orthographic projection, on the base substrate, of the sub-scanning line; and
the connection line is connected to the sub-scanning line through the first through-hole, and the first through-hole has an aperture of not less than 3 μm.

In an embodiment of the present disclosure, as for the two adjacent sub-scanning lines, a second gap is provided between the tail end of the first sub-scanning line and the head end of the second sub-scanning line in the second direction; and
an orthographic projection, on the base substrate, of the second gap is at least partially overlapped with the orthographic projection, on the base substrate, of the first through-hole.

In an embodiment of the present disclosure, the orthographic projection, on the base substrate, of the first through-hole is located within the orthographic projection, on the base substrate, of the connection line; and
wherein an interval, in the first direction, between an edge of the first through-hole and an end surface of the connection line is not less than 1.5 μm.

In an embodiment of the present disclosure, the sub-scanning line has a length of no more than 6 mm.

In an embodiment of the present disclosure, the plurality of transistors are arranged to form rows along an extension direction of the scanning line, every three transistors in a same row of transistors are connected to a same sub-scanning line, and the sub-scanning line has a length of 90-200 μm.

In an embodiment of the present disclosure, the connection line is located between transistors of two adjacent sub-pixel area arranged in an extension direction of the scanning line.

A second aspect of the present disclosure provides a display panel including:
the array substrate according to the first aspect;
a color film substrate, provided on a side of the array substrate and including a color film layer, the color film layer including a light-shielding portion and a plurality of filtering portions defined by the light-shielding portion, and the filtering portions being provided to respectively correspond to the sub-pixel areas in a direction perpendicular to the base substrate; and
a liquid crystal layer, provided between the array substrate and the color film substrate,
wherein an orthographic projection, on the base substrate, of the connection line is located within an orthographic projection, on the base substrate, of the light-shielding portion.

A third aspect of the present disclosure provides a display device including a display panel according to the second aspect.

### BRIEF DESCRIPTION OF THE DRAWINGS

The foregoing and other features and advantages of the present disclosure will become more apparent by describing the example embodiments thereof in detail with reference to the accompanying drawings.

FIG. 1 is a schematic structure diagram of an array substrate in an embodiment of the present disclosure

FIG. 2 is a schematic structure diagram of an array substrate in another embodiment of the present disclosure;

FIG. 3 is a schematic structure diagram of an arrangement of a sub-scanning line and a connection line in an embodiment of the present disclosure;

FIG. 4 is a schematic structure diagram of an arrangement of a sub-scanning line and a connection line in another embodiment of the present disclosure;

FIG. 5 is a schematic structure diagram of an arrangement of a sub-scanning line and a connection line in yet another embodiment of the present disclosure;

FIG. 6 is a schematic structure diagram of an arrangement of a sub-scanning line and a connection line in yet another embodiment of the present disclosure;

FIG. 7 is an enlarged view of part A in FIG. 1;

FIG. 8 is an enlarged view of part B in FIG. 2;

FIG. 9 is a schematic diagram of a connection structure of the sub-scanning line and the connection line in FIG. 1;

FIG. 10 is a schematic diagram of a connection structure of the sub-scanning line and the connection line in FIG. 2;

FIG. 11 is a schematic diagram of a connection manner of a sub-scanning line and a connection line in yet another embodiment of the present disclosure;

FIG. 12 is a schematic structure diagram of a sub-scanning line in an embodiment of the present disclosure;

FIG. 13 is a schematic diagram of a stack structure of a display panel in an embodiment of the present disclosure;

FIG. 14 is a schematic diagram of a planar structure of a display panel in an embodiment of the present disclosure;

FIG. 15 is a schematic diagram of a planar structure of a display panel in another embodiment of the present disclosure.

### DETAILED DESCRIPTION

Example embodiments will now be described more fully with reference to the accompanying drawings. However, the example embodiments can be implemented in a variety of forms and should not be construed as being limited to the embodiments set forth herein; rather, these embodiments are provided so that the present disclosure is comprehensive and complete and the concept of the example embodiments is conveyed completely to a person skilled in the art. The described features, structures, or characteristics may be combined in one or more embodiments in any suitable manner. In the following description, many specific details are provided for a full understanding of the embodiments of the present disclosure.

In the figures, the thickness of a region and a layer may be exaggerated for clarity. The same reference numerals in the figures denote the same or similar structures, and thus detailed descriptions thereof will be omitted.

The described features, structures, or characteristics may be combined in any suitable manner in one or more embodiments. In the following description, numerous specific details are provided for a thorough understanding of the embodiments of the present disclosure. However, those skilled in the art will recognize that the technical solutions of the present disclosure may be practiced without one or more of the specific details, or with other methods, components, devices, steps, or the like. In other instances, well-known structures, materials, or operations are not shown or described in detail to avoid obscuring aspects of the present disclosure.

When a structure is “on” another structure, it may refer to that the structure is integrally formed on said another structure, or that the structure is “directly” arranged on said another structure, or that the structure is “indirectly” arranged on said another structure through an additional structure.

The terms “a”, “an”, and “the” are used to indicate the presence of one or more elements/components/etc. The terms “including” and “having” are used in an open-ended manner, and refer to that there may be additional elements/components/etc. in addition to the listed elements/components/etc. The terms “first”, “second” or the like are used only as symbols without limiting the quantity of the objects thereof.

In the present disclosure, an acute angle, a right angle, an obtuse angle, “perpendicular”, “parallel”, and “equal” means that a corresponding structure may approximately have an acute angle, right angle or obtuse angle, or may approximately be in a perpendicular, parallel, or equal state within an allowed error range of process, measurement, or the like. The allowed error range of process and measurement may be determined according to actual operation, for example, the error range may be no more than +5%, which however is not limited thereto.

A TFT-LCD (thin film transistor liquid crystal display) display panel includes scanning lines and data lines and transistors located within the area defined by the scanning lines and data lines. The scanning line is connected to a gate electrode of the transistor. Currently, the scanning line is generally a continuous, long and straight metal line. At this stage, the size, in a row direction, of a display area of a large-size display panel is mostly 70-1000 mm, and the length of the scanning line is approximately the same as the size of the display area in the row direction. Due to the antenna effect, during the manufacturing process of the display panel, the scanning line may continuously collect charge, resulting in an increase of the potential thereof, and when the charge accumulated exceeds a certain amount, a tunnelling current may be formed in a gate oxide layer between the gate electrode and the active layer, resulting in a short-circuiting of the gate electrode and the active layer, which will lead to a failure of the thin-film transistor, therefore defects such as bright spot and short circuit may occur.

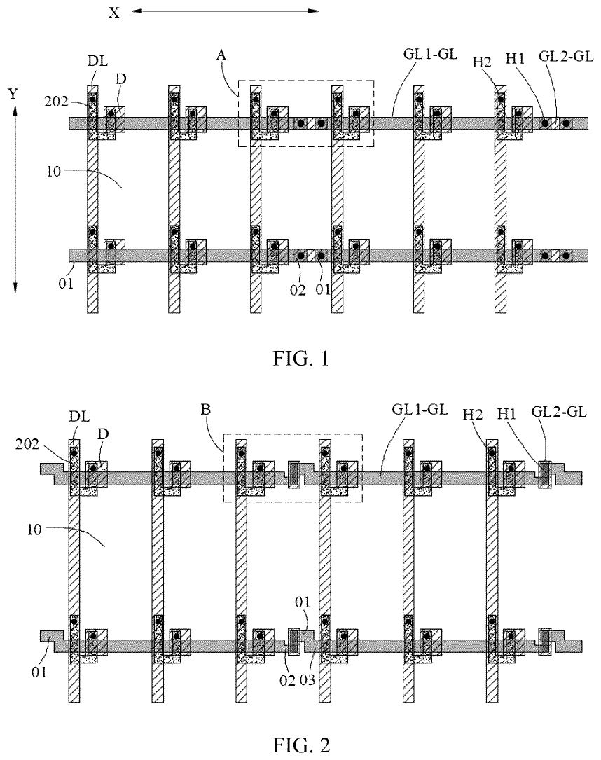

As shown in FIGS. 1 to 6, an implementation of the present disclosure provides an array substrate including a plurality of scanning lines GL and a plurality of data lines DL, and the plurality of data lines DL are intersected with the plurality of scanning lines GL to define a plurality of sub-pixel areas 10. The scanning line GL includes a plurality of sub-scanning lines GL1 spaced apart from each other and a connection line GL2 connecting two adjacent sub-scanning lines GL1. The array substrate further includes a base substrate 1 and a plurality of conductive layers provided on a side of the base substrate 1. The sub-scanning line GL1 and the connection line GL2 are arranged in different conductive layers.

In the array substrate provided by the present disclosure, the scanning line GL includes a plurality of sub-scanning lines GL1 spaced apart from each other and a connection line GL2 connecting two adjacent sub-scanning lines GL1, and the sub-scanning line GL1 and the connection line GL2 are arranged in different conductive layers respectively. The present disclosure partitions the scanning line GL into a plurality of sub-scanning lines GL1 with a shorter length, which can reduce the amount of charge collected by the scanning line GL, avoid the antenna effect of the array substrate, reduce the defects due to the antenna effect, and thus improve the yield and reliability of the product.

Various components of the array substrate provided by the implementation of the present disclosure are described in detail below in conjunction with the accompanying drawings.

The present disclosure provides an array substrate which may be used to form a TFT-LCD (Thin Film Transistor Liquid Crystal Display) display panel such as an LTPS (Low Temperature Poly-Silicon) liquid crystal display panel.

As shown in FIGS. 1 and 2, the array substrate includes a plurality of scanning lines GL and a plurality of data lines DL, and the plurality of data lines DL are intersected with the plurality of scanning lines GL to define a plurality of sub-pixel areas 10.

The scanning lines GL may extend substantially along a first direction X and be arranged along a second direction Y, and the data lines DL may extend along the second direction Y and be arranged along the first direction X. It should be noted herein that an angle between the first direction X and the second direction Y may be any angle greater than 0° and less than or equal to 90°, which is not specifically limited in the present disclosure.

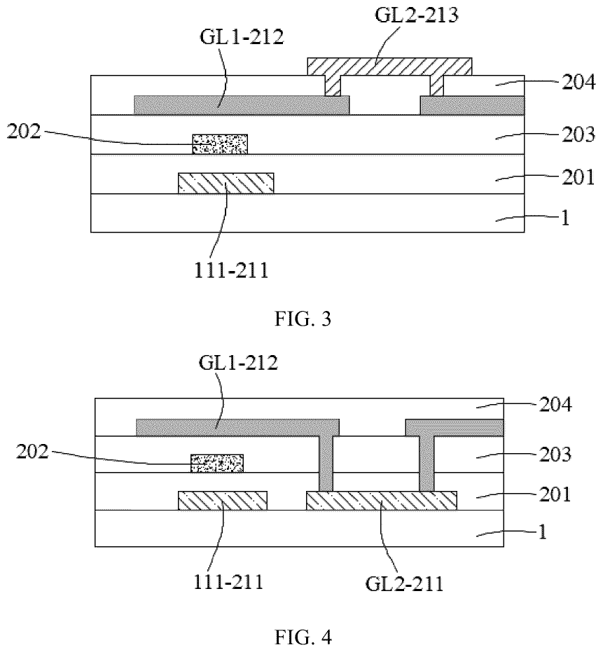

As shown in FIGS. 3 to 6, the array substrate further includes a base substrate 1 and a plurality of conductive layers provided on a side of the base substrate 1, and the sub-scanning line GL1 and the connection line GL2 are arranged in different conductive layers, respectively. By way of example, the plurality of conductive layers include at least two conductive layers, the sub-scanning line GL1 is arranged in one of the plurality of conductive layers, and the connection line GL2 is arranged in another conductive layer.

As for the antenna effect, the longer the length of the scanning line GL, the more the charges collected by the scanning line in the manufacturing process, and the greater the failure risk the transistor. The present disclosure partitions the scanning line GL into a plurality of sub-scanning lines GL1 with a shorter length, which helps to reduce the amount of charge collected by the scanning line GL, and reduce the failure risk of the transistor.

The base substrate 1 may be of an inorganic material or an organic material. By way of example, in an implementation of the present disclosure, the material of the base substrate 1 may be a glass material such as soda-lime glass, quartz glass, sapphire glass, and the like or may be a metal material such as stainless steel, aluminium, nickel and the like. In another implementation of the present disclosure, the material of the base substrate 1 may be a polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN), or a combination thereof. The base substrate 1 may also be a flexible base substrate. By way of example, in an implementation of the present disclosure, the material of the base substrate 1 may be polyimide (PI). The base substrate 1 may also be a composite of a plurality of material layers. By way of example, in an implementation of the present disclosure, the base substrate 1 may include a bottom film layer, a pressure-sensitive adhesive layer, a first polyimide layer, and a second polyimide layer, which are stacked in that order.

As shown in FIGS. 1 and 2, the array substrate further includes a plurality of transistors, and the plurality of transistors are provided in respective sub-pixel areas 10 in one-to-one correspondence. In an embodiment, an orthographic projection of the connection line GL2 on the base substrate 1 is not overlapped with an orthographic projection of the transistor on the base substrate 1. Further, the connection line GL2 may be provided between the transistors of two adjacent sub-pixel areas 10 arranged along an extension direction of the scanning line GL (the first direction X).

As shown in FIGS. 3 to 6 and FIG. 13, the plurality of conductive layers are provided on a side of the base substrate 1. The plurality of conductive layers may include two, three, four, or more conductive layers, and the materials of different conductive layers may be different. The sub-scanning line GL1 and the connection line GL2 are arranged in different conductive layers. The sub-scanning line GL1 and the connection line GL2 may be arranged in the plurality of conductive layers in various ways.

In some embodiments of the present disclosure, the plurality of conductive layers includes a first conductive layer 212 and a second conductive layer 213. The first conductive layer 212 is provided on a side of the base substrate 1, the first conductive layer 212 includes a gate electrode G of the transistor, the second conductive layer 213 is provided on a side of the first conductive layer 212 away from the base substrate 1, the second conductive layer 213 includes a source electrode S and a drain electrode D of the transistor, the sub-scanning line GL1 is arranged in the first conductive layer 212, and the connection line GL2 is arranged in the second conductive layer 213.

As shown in FIGS. 3, 4, and 13, in a specific embodiment, the plurality of conductive layers further includes a third conductive layer 211, the third conductive layer 211 is provided between the base substrate 1 and the first conductive layer 212, and the third conductive layer 211 includes a light-shielding structure 111.

In some other embodiments of the present disclosure, the plurality of conductive layers includes a first conductive layer 212, a second conductive layer 213, and a third conductive layer 211. The first conductive layer 212 is provided on a side of the base substrate 1, the first conductive layer 212 includes a gate electrode G of the transistor, the second conductive layer 213 is provided on the side of the first conductive layer 212 away from the base substrate 1, the second conductive layer 213 includes a source electrode S and a drain electrode D of the transistor, the third conductive layer 211 is provided between the base substrate 1 and the first conductive layer 212, and the third conductive layer 211 includes a light-shielding structure 111. In such type of embodiment, the connection line GL2 is arranged in the third conductive layer 211.

The material of the third conductive layer 211 may include a conductive material such as a metal or an alloy. When the connection line GL2 is arranged in the third conductive layer 211, as shown in FIG. 4, a conductive material layer may be formed by first depositing a metal or alloy material on a side of the base substrate 1, and then the conductive material layer may be patterned, so that the connection line GL2 and the light-shielding structure 111 are obtained. The material of the first conductive layer 212 may include a metal, an alloy or a transparent conductive material such as copper, ITO (indium tin oxide), IZO (indium zinc oxide). The sub-scanning line GL1 is arranged in the first conductive layer 212, and in the manufacturing process, a conductive material layer may be formed by depositing a conductive material on the side of the third conductive layer 211 away from the base substrate 1, and then the conductive material layer is patterned, so that the gate electrode G of the transistor and the sub-scanning line GL1 are obtained. The material of the second conductive layer 213 may include a metal, an alloy, or transparent conductive material. Similarly, when the connection line GL2 is arranged in the second conductive layer 213, as shown in FIG. 3, a conductive material layer may be formed by first depositing the metal, alloy or transparent conductive material on the side of the first conductive layer 212 away from the base substrate 1, and then the conductive material layer may be patterned, so that the source electrode S and the drain electrode D of the transistor, and the connection line GL2 are obtained.

In an embodiment, the array substrate further includes an active layer 202, a first gate insulating layer 203, and an interlayer dielectric layer 204. The active layer 202 is provided between the base substrate 1 and the first conductive layer 212, and the active layer 202 includes an active region of the transistor. The material of the active layer 202 may include a conductive material such as polysilicon. The first gate insulating layer 203 is provided between the active layer 202 and the first conductive layer 212, and the first gate insulating layer 203 covers a surface of the active layer 202. An orthographic projection of the first conductive layer 212 on the base substrate 1 and an orthographic projection of the active layer 202 on the base substrate 1 are at least partially overlapped with each other, a region of the first conductive layer 212 corresponding to the overlapping portion forms the gate electrode G of the transistor, and a region of the active layer 202 corresponding to the overlapping portion forms a channel region of the transistor. The interlayer dielectric layer 204 is provided between the first conductive layer 212 and the second conductive layer 213, and the interlayer dielectric layer 204 covers a surface of the first conductive layer 212. The source electrode S and the drain electrode D of the transistor in the second conductive layer 213 are connected to the active layer 202. The first gate insulating layer 203 and the interlayer dielectric layer 204 are provided with a second through-hole H2 passing through the first gate insulating layer 203 and the interlayer dielectric layer 204, and the source electrode S and the drain electrode D of the transistor in the second conductive layer 213 are connected to the active layer via the second through-hole H2, and the aperture of the second through-hole H2 is not less than 2.8 μm.

As shown in FIG. 3, when the connection line GL2 is arranged in the second conductive layer 213, in comparison with the current process, the partitioning of the scanning line GL and the manufacturing of the array substrate may be completed without an additional photolithography process. Specifically, in the current manufacturing process of the array substrate, after the interlayer dielectric layer 204 is formed, a photolithography process is usually carried out to form a through-hole in the interlayer dielectric layer 204 and the first gate insulating layer 203, so that the source terminal S and the drain electrode terminal D of the transistor in the second conductive layer 213 are connected to the corresponding active layer 202. Accordingly, when the connection line GL2 is arranged in the second conductive layer 213, the same lithography process may also be employed to form a through-hole in the interlayer dielectric layer 204 which exposes a portion of the surface of the sub-scanning line GL1. Subsequently, the second conductive layer 213 is formed, at which point the connection line GL2 in the second conductive layer 213 may be connected to the sub-scanning line GL1 through the through-hole. This solution does not require an additional photolithography process, and the process is simple and less costly.

As shown in FIG. 4, when the plurality of conductive layers further includes the third conductive layer 211, the array substrate also includes a buffer layer 201. The buffer layer 201 and the first gate insulating layer 203 are stacked between the third conductive layer 211 and the first conductive layer 212 along the direction away from the base substrate 1. Specifically, the buffer layer 201 is provided between the third conductive layer 211 and the first conductive layer 212, and the buffer layer 201 covers the surface of the third conductive layer 211.

When the connection line GL2 is arranged in the third conductive layer 211, in compassion with the current process, an additional photolithography process may be further needed. Specifically, in the current manufacturing process of array substrate, there is no photolithography process for forming a through-hole before forming the first conductive layer 212. Instead in an embodiment, in order to realize the connection between the sub-scanning line GL1 and the connection line GL2, an additional photolithographic process is further performed after forming the first gate insulating layer 203 to form a through-hole in the first gate insulating layer 203 and the buffer layer 201 which exposes a portion of the surface of the connection line GL2. Subsequently, the first conductive layer 212 is formed, at which point the sub-scanning line GL1 in the first conductive layer 212 may be connected to the connection line GL2 via the through-hole.

As shown in FIGS. 1 and 2, in some embodiments of the present disclosure, the data line DL is arranged in the second conductive layer 213, and the data line DL is connected to the source electrode S/drain electrode D of the transistor. Of course, the data line DL may also be arranged in another conductive layer, which is not limited in the present disclosure.

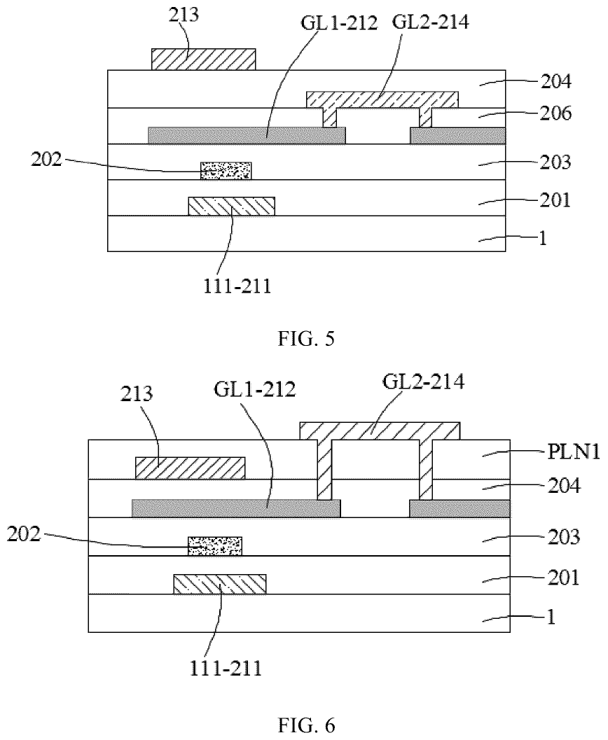

As shown in FIGS. 5 and 6, in some other embodiments of the present disclosure, the plurality of conductive layers further includes a fourth conductive layer 214. The fourth conductive layer 214 may be provided in the plurality of conductive layers in various positions. By way of example, the fourth conductive layer 214 may be provided on a side of the third conductive layer 211 close to the base substrate 1, or between the third conductive layer 211 and the first conductive layer 212, or between the first conductive layer 212 and the second conductive layer 213, or on a side of the second conductive layer 213 away from the base substrate 1. In such type of embodiment, the connection line GL2 is arranged in the fourth conductive layer 214 and the sub-scanning line GL1 is arranged in the first conductive layer 212.

As shown in FIG. 5, when the fourth conductive layer 214 is provided between the first conductive layer 212 and the second conductive layer 213, the fourth conductive layer 214 may also include a drain electrode of the transistor. The array substrate further includes a second gate insulating layer 206 provided between the first conductive layer 212 and the fourth conductive layer 214. As shown in FIG. 6, when the fourth conductive layer 214 is provided on the side of the second conductive layer 213 away from the base substrate 1, the data line DL may be arranged in the fourth conductive layer 214. The array substrate further includes a first planarization layer PLN1 provided between the second conductive layer 213 and the fourth conductive layer 214. It should be noted herein that the location of the fourth conductive layer 214 and the structure thereof are only illustrated herein by way of example, which does not limit the present disclosure.

In the manufacturing process of array substrate, the probability that the antenna effect occurs is usually measured by an “antenna ratio”. The antenna ratio is a ratio of the area of the conductor constituting the so-called “antenna” to the area of the gate connected therewith, wherein the area of the gate is the area of the channel region of the transistor. The larger the area of the conductor constituting the so-called “antenna” or the smaller the area of the gate connected therewith, the greater the probability that the antenna effect occurs. With the development of display technology, the size of the sub-pixel is getting smaller and smaller, and the size of the channel region of the transistor is also getting smaller and smaller, and the probability that the antenna effect occurs is getting larger and larger. In order to ensure the display quality of the display panel and to meet the higher demand of the user on the display, the present disclosure reduces the probability that the antenna effect occurs by changing the length of the conductor constituting the so-called “antenna” while keeping the size of the transistor unchanged.

The antenna ratio is determined by factors such as process conditions, process capability, and type of thin film transistor, and the empirical data shows that when the antenna ratio is less than or equal to 3000, the antenna effect may be effectively avoided, resulting in an occurrence rate of defects of less than 0.5%. For most products, the antenna effect may be effectively avoided when the length of the structure constituting the so-called “antenna” does not exceed 6 mm. In the present disclosure, the length of each sub-scanning line GL1 is less than 6 mm, and it should be noted that the length of each sub-scanning line refers to the dimension thereof in the first direction X. The lengths of respective sub-scanning line GL1 may be or may be not equal to each other as long as it does not exceed 6 mm. In an embodiment, the respective sub-scanning line GL1 have substantially the same length.

As shown in FIGS. 1, 2, 7 and 8, in some embodiments of the present disclosure, the scanning line GL extends along the first direction X, and the sub-scanning lines GL1 are arranged along the first direction X. The sub-scanning line GL1 has a head end 01 and a tail end 02, and the tail end 02 of a previous sub-scanning line GL1 is connected to the head end 01 of a next sub-scanning line GL1 by the connection line GL2. An orthographic projection, on the base substrate 1, of the connection line GL2 connecting two adjacent sub-scanning lines GL1 is at least partially overlapped with orthographic projections of the two sub-scanning lines GL1 on the base substrate 1. Specifically, one end of the orthographic projection of the connection line GL2 on the base substrate 1 is at least partially overlapped with the orthographic projection of the tail end 02 of the previous sub-scanning line GL1 on the base substrate 1, and the other end of the orthographic projection of the connection line GL2 on the base substrate 1 is at least partially overlapped with the orthographic projection of the head end 01 of the next sub-scanning line GL1 on the base substrate 1. The size and positional relationship of the connection line GL2 and the sub-scanning line GL1 may be set according to actual needs.

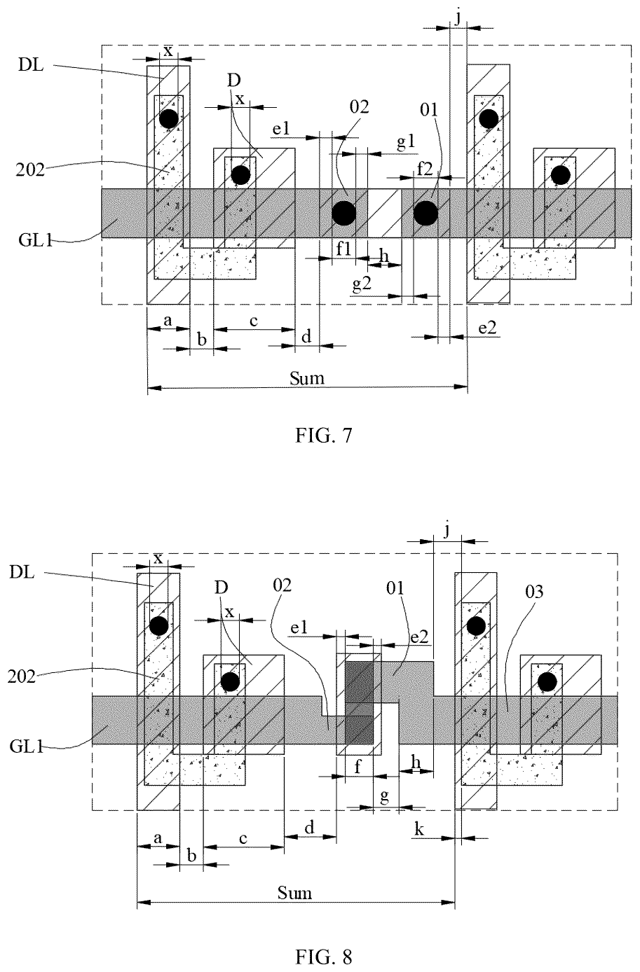

As shown in FIGS. 1 and 7, in some embodiments of the present disclosure, as for the two adjacent sub-scanning lines GL1, a second sub-scanning line GL1 thereof is provided at a side, away from the head end 01 of a first sub-scanning line GL1 thereof in the first direction X, of the tail end 02 of the first sub-scanning line GL1. In an embodiment, the sub-scanning lines GL1 are spaced apart along the first direction X. As for the two adjacent sub-scanning lines GL1, an interval h between the tail end 02 of the first sub-scanning line GL1 and the head end 01 of the second sub-scanning line GL1 is not less than 3 μm. The interval h is only an example, and in practice, the interval h may be adjusted in accordance with the process requirements of different panels. For example, in an embodiment, the interval between metal lines in the same layer is at least 3.5 μm, and the interval between the tail end 02 of the first sub-scanning line GL1 and the head end 01 of the second sub-scanning line GL1 is not less than 3.5 μm. Of course, the interval may be other values, which may be set according to the material and width of the metal line and so on.

As shown in FIGS. 1 and 7, in such type of embodiment, the dimension or size of other connection structures involving the sub-scanning line GL1 and the connection line GL2 may be set according to actual needs. When the connection line GL2 is arranged in the second conductive layer 213, the interlayer dielectric layer 204 is provided with a first through-hole H1 passing through the interlayer dielectric layer 204, the orthographic projection of the first through-hole H1 on the base substrate 1 is at least partially overlapped with the orthographic projection of the sub-scanning line GL1 on the base substrate 1, and the orthographic projection of the first through-hole H1 on the base substrate 1 is at least partially overlapped with the orthographic projection of the connection line GL2 on the base substrate 1. The connection line GL2 is connected to the sub-scanning line GL1 via the first through-hole H1. The orthographic projection of the first through-hole H1 on the base substrate 1 may be a circle, an ellipse, a rectangle, a regular polygon, or a closed irregular figure, which is not specifically limited in the present disclosure. The aperture f1 or f2 of the first through-hole H1 is not less than 3 μm. It should be noted herein that the aperture of the first through-hole H1 may be different in different directions, but the minimum aperture thereof is not less than 3 μm.

When the connection line GL2 is arranged in the third conductive layer 211, the buffer layer 201 and the first gate insulating layer 203 are provided with a first through-hole H1 passing through the buffer layer and the first gate insulating layer. The setting of the first through-hole H1 may refer to the first through-hole H1 in the interlayer dielectric layer 204 of the above embodiment, which will not be described in detail herein.

The first through-hole H1 includes a head end through-hole and a tail end through-hole, the tail end through-hole is provided at the tail end 02 of the first sub-scanning lines GL1 of the two adjacent sub-scanning lines GL1, and the head end through-hole is provided at the head end 01 of the second sub-scanning lines GL1 of the two adjacent sub-scanning lines GL1. An interval g1, in the first direction X, between an edge of the tail end through-hole and an end surface of the tail end 02 of the first sub-scanning line GL1 of the two adjacent sub-scanning lines GL1 is not less than 2.1 μm, and an interval g2, in the first direction X, between an edge of the head end through-hole and an end surface of the head end 01 of the second sub-scanning line GL1 of the two adjacent sub-scanning lines GL1 is not less than 2.1 μm. In this example, the distance between the end surface of the sub-scanning line GL1 and the edge of the first through-hole H1 is limited so as to increase the stability of the sub-scanning line GL1 when the sub-scanning line GL1 is connected to the connection line GL2 via the first through-hole H1 to ensure the yield of the product.

Similarly, further, the distance between the end surface of the connection line GL2 and the edge of the first through-hole H1 may also be limited. For example, the orthographic projection of the first through-hole H1 on the base substrate 1 is located within the orthographic projection of the connection line GL2 on the base substrate 1, an interval e1, in the first direction X, between the edge of the tail end through-hole and an end surface of the connection line GL2 is not less than 2.1 μm, and an interval e2, in the first direction X, between the edge of the head end through-hole and the end surface of the connection line GL2 is not less than 2.1 μm. It should be noted herein that both the distance between the end surface of the scanning line GL1 and the edge of the first through-hole H1 and the distance between the end surface of the connection line GL2 and the edge of the first through-hole H1 can be adjusted according to the actual needs.

In the present disclosure, the length of the sub-scanning line GL1 may be set according to actual product requirements and process requirements. For example, the length of the sub-scanning line GL1 may be set according to the dimension of the transistor in the first direction X as well as the line width of the metal line such as the data line DL or the interval between the conductive structures such as the interval between the data line DL and the transistor.

For example, the sub-scanning line GL1 is arranged in the first conductive layer 212, the connection line GL2 and the data line DL are arranged in the second conductive layer 213, and the second conductive layer 213 further includes the source electrode S and the drain electrode D of the transistor. An interval b, in the first direction X, between the data line DL and the drain electrode D of the transistor is not less than 2.9 μm, an interval d, in the first direction X, between the drain electrode D of the transistor and the connection line GL2 is not less than 3 μm, and an interval j, in the first direction X, between the connection line GL2 and the data line DL is not less than 3 μm. In addition, the line width of the data line DL and the dimension in the first direction X of the second electrode plate C2 may also affect the length of the sub-scanning line GL1. In an embodiment, the line width a of the data line DL is not less than 3.3 μm, and the dimension c in the first direction X of the drain electrode D of the transistor is not less than 9.4 μm. Of course, the line width of the data line DL and the dimension in the first direction X of the drain electrode D of the transistor may be adaptively changed according to the actual product, and the foregoing is only an example, which doe not limit the present disclosure.

Based on the dimensional limitation of each of the above-described structures, when the second sub-scanning line GL1 of the two adjacent sub-scanning lines GL1 is provided at the side, away from the head end 01 of the first sub-scanning line GL1 in the first direction X, of the tail end 02 of the first sub-scanning line GL1, the dimension in the first direction X of the sub-pixel area 10 is not less than 39.8 μm. The specific values may refer to Table 1.

TABLE 1

| Reference sign | a | b | c | d | e1 | f1 | g1 |
|---|---|---|---|---|---|---|---|
| Minimum dimension (μm) | 3.3 | 2.9 | 9.4 | 3 | 2.1 | 3 | 2.1 |

| Reference sign | h | g2 | f2 | e2 | j | Sum |
|---|---|---|---|---|---|---|
| Minimum dimension (μm) | 3 | 2.1 | 3 | 2.1 | 3 | 39 |

In the related art, in an array substrate, the sub-pixel areas 10 are arranged in an array, and the gate electrode of a transistor in each sub-pixel area 10 may be connected to a scanning line GL, and usually the transistors in the same row may be connected to the same scanning line GL. However in the present disclosure, a plurality of transistors are arranged along the extension direction of the scanning line GL (the first direction X) to form a row, and among the transistors in the same row, every two, three, or four transistors may be connected to the same sub-scanning line GL1, i.e., one sub-scanning line GL1 corresponds to two, three, or four sub-pixel areas 10. In this case, the length of the sub-scanning line GL1 is related to the number of sub-pixel areas 10 corresponding thereto. For example, when one sub-scanning line GL1 corresponds to three sub-pixel areas 10, the length of the sub-scanning line GL1 is about 39×3=117 μm. It should be noted herein that the length of the sub-scanning line GL1 may fluctuate around 117 μm due to the influence of other structures such as the first through-hole H1, the connection line GL2, and so on, and the fluctuation range is determined by the actual product and process requirements, which is not specifically limited in the present disclosure. Of course, one sub-scanning line GL1 may also correspond to five or more sub-pixel areas 10 as long as the length thereof does not exceed 6 mm. In an embodiment, among the transistors in the same row, every three transistors are connected to the same sub-scanning line GL1, and the length of the sub-scanning line GL1 is 90-200 μm. The length of the sub-scanning line GL1 may be different for different products.

As shown in FIGS. 2 and 8, in other embodiments of the present disclosure, the sub-scanning line GL1 further includes an intermediate portion 03 provided between the head end 01 and the tail end 02. As for the two adjacent sub-scanning lines GL1, the intermediate portion 03 of the second sub-scanning line GL1 is provided at a side, away from the head end 01 of the first sub-scanning line GL1 in the first direction X, of the tail end 02 of the first sub-scanning line GL1, and the head end 01 of the second sub-scanning line GL1 is provided at a side, in a second direction Y, of the tail end 02 of the first sub-scanning line GL1. In an embodiment, the second direction Y is perpendicular to the first direction X. In an embodiment, a part of the structures of the two adjacent sub-scanning lines GL1 are arranged longitudinally in the second direction Y. This arrangement reduces the size of the transverse arrangement of the sub-scanning lines GL1 in the first direction X, which helps to reduce the transverse size of the sub-pixel area 10 in the first direction X, and to increase the PPI (pixels per inch) of the display panel.

In such type of embodiment, a first gap is provided between the two adjacent sub-scanning lines GL1 in the first direction X, and the first gap has a dimension g in the first direction X of not less than 2.4 μm. The gap dimension is only an example, and in practice, the first gap may be adjusted in accordance with the process requirements of different panels. For example, in an embodiment, if a minimum interval between metal lines in the same layer is 3 μm, the first gap is not less than 3 μm. Of course, the first gap may also be other values, which may be specifically set according to the material and the line width of the metal line and the like.

In such type of embodiment, the array substrate may also include an active layer 202, a first gate insulating layer 203, an interlayer dielectric layer 204, and the like, and the manner in which each layer is provided may be referred to the above embodiments, and will not be described in detail herein. Of course, a buffer layer 201 may also be included.

In an embodiment, when the connection line GL2 is arranged in the second conductive layer 213, the interlayer dielectric layer 204 is provided with a first through-hole H1 passing through the interlayer dielectric layer 204. When the connection line GL2 is arranged in the third conductive layer 211, the buffer layer 201 and the first gate insulating layer 203 are provided with a first through-hole H1 passing through the buffer layer and the first gate insulating layer. The orthographic projection of the first through-hole H1 on the base substrate 1 is at least partially overlapped with the orthographic projection of the sub-scanning line GL1 on the base substrate 1. The connection line GL2 is connected to the sub-scanning line GL1 via the first through-hole H1. The orthographic projection of the first through-hole H1 on the base substrate 1 may be a circle, an ellipse, a rectangle, a regular polygon, a closed irregular figure or the like, which is not specifically limited in the present disclosure. The aperture f of the first through-hole H1 is not less than 3 μm.

In a specific embodiment, as for the two adjacent sub-scanning lines GL1, a second gap is provided between the tail end 02 of the first sub-scanning line GL1 and the head end 01 of the second sub-scanning line GL1 in the second direction Y, and an orthographic projection, on the base substrate 1, of the second gap is at least partially overlapped with the orthographic projection, on the base substrate 1, of the first through-hole H1. The orthographic projection of the first through-hole H1 on the base substrate 1 is located within the orthographic projection of the connection line GL2 on the base substrate 1, and the interval e1 or e2 in the first direction X between the edge of the first through-hole H1 and the end surface of the connection line GL2 is not less than 1.5 μm.

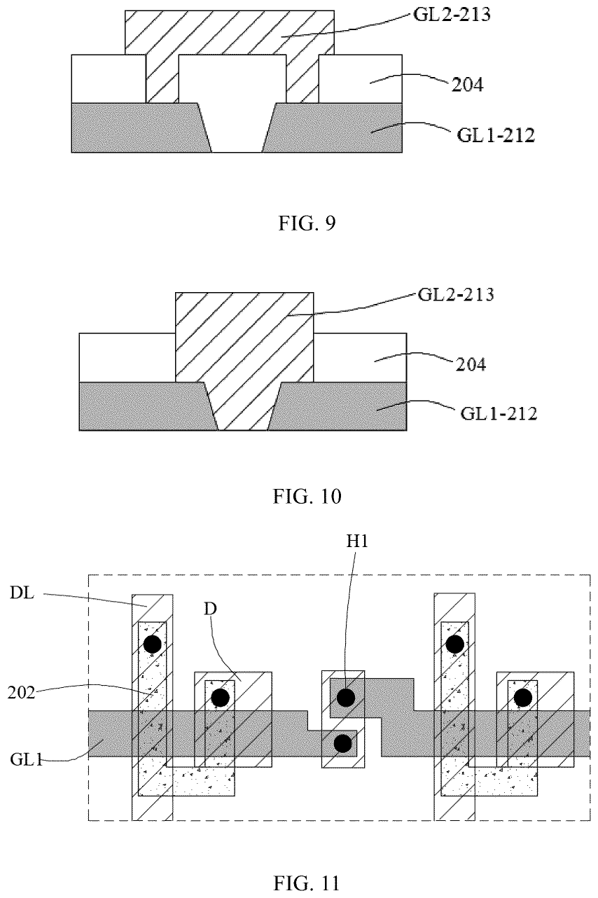

In an embodiment, orthographic projections, on the base substrate 1, of the second gap and the first through-hole H1 are at least partially overlapped with each other, which may help to reduce the dimension of the connection line GL2. For example, when the sub-scanning line GL1 is arranged in the first conductive layer 212 and the connection line GL2 is arranged in the second conductive layer 213, since the orthographic projections, on the base substrate 1, of the second gap and the first through-hole H1 are at least partially overlapped with each other, a portion of the connection line GL2 formed may be provided within the second gap, as shown in FIG. 10, this portion may connect opposite surfaces of two adjacent sub-scanning lines GL1. This manner does not need to consider the distance between the end surface of the sub-scanning line GL1 and the edge of the first through-hole H1, and thus, to a certain extent, helps to reduce the dimension of the connection line GL2. Of course, in an embodiment, the first through-hole H1 may also include a head end through-hole and a tail end through-hole, as in the embodiments shown in FIGS. 1, 7, and 9, as long as it can satisfy the need for connecting two adjacent sub-scanning lines GL1.

As also shown in FIGS. 2 and 8, in such type of embodiment, the length of the sub-scanning line GL1 may likewise be set according to actual product requirements and process requirements. The sub-scanning line GL1 is arranged in the first conductive layer 212, the connection line GL2 and the data line DL are arranged in the second conductive layer 213, and the second conductive layer 213 also includes a source electrode S and a drain electrode D of the transistor. The interval b in the first direction X between the data line DL and the drain electrode D of the transistor is not less than 2.9 μm, the interval d in the first direction X between the drain electrode D of the transistor and the connection line GL2 is not less than 3 μm, and the interval in the first direction X between the connection line GL2 and the data line DL is not less than 5.1 μm.

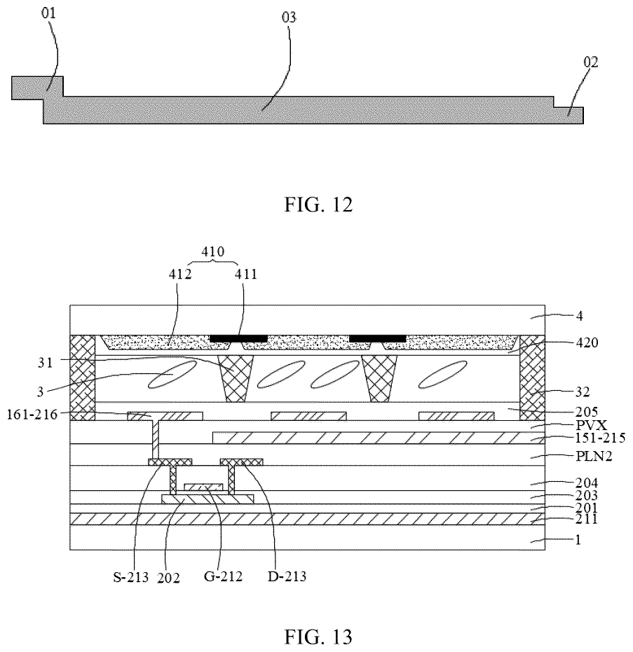

It should be noted herein that the interval in the first direction X between the connection line GL2 and the data line DL is related to the actual structure of the sub-scanning line GL1 and the like. As shown in FIG. 12, the two ends of the sub-scanning line GL1 are substantially in the shape of steps to facilitate the arrangement in the second direction Y of the two adjacent sub-scanning lines GL2. The interval j between the head end 01 of the second sub-scanning line GL1 and the active layer 202 is not less than 1.25 μm. The length h in the first direction of the head end 01 of the second sub-scanning line GL1 is not less than 3.5 μm. The interval k in the first direction X between the edge of the data line DL and the active layer is not less than 0.55 μm. The interval in the first direction X between the connection line GL2 and the data line DL is not less than g+h+j−k−e2=5.1 μm. It should be noted herein that the description herein is also only an example, and that when the structure of the connection line GL2 is changed or when product requirements differ, the dimension is adjusted accordingly.

In addition, the line width of the data line DL and the dimension in the first direction X of the second electrode plate C2 may also affect the length of the sub-scanning line GL1. As also shown in FIG. 8, the line width a of the data line DL is not less than 3.3 μm, and the dimension c in the first direction X of the drain electrode D of the transistor is not less than 9.4 μm. Of course, the line width of the data line DL and the dimension in the first direction X of the drain electrode D of the transistor may be adaptively changed according to the actual product, and the foregoing is only an example, which does not limit the present disclosure.

Based on the dimensional limitation of each of the above-described structures, when as for the two adjacent sub-scanning lines GL1, the head end 01 of the second sub-scanning line GL1 is provided at a side, in the second direction Y, of the tail end 02 of the first sub-scanning line GL1, the sub-pixel area 10 has a dimension of not less than 29.7 μm in the first direction X. The specific values may refer to Table 2.

TABLE 2

| Reference sign | a | b | c | d | e1 | f | e2 |
|---|---|---|---|---|---|---|---|
| Minimum dimension (μm) | 3.3 | 2.9 | 9.4 | 3 | 1.5 | 3 | 1.5 |

| Reference sign | g | h | j | k | Sum |
|---|---|---|---|---|---|
| Minimum dimension (μm) | 2.4 | 3.5 | 1.25 | 0.55 | 29.7 |

In an embodiment, the dimension of the sub-pixel area 10 is smaller than that of the sub-pixel area 10 in the embodiment of FIG. 7, which may be applied to the design of a large-size product to meet the high PPI design requirement thereof.

In an embodiment, among the transistors in the same row, every two, three, or four transistors may be connected to the same sub-scanning line GL1, i.e., one sub-scanning line GL1 corresponds to two, three, or four sub-pixel areas 10. In this case, the length of the sub-scanning line GL1 is related to the number of sub-pixel areas 10 corresponding thereto. For example, when one sub-scanning line GL1 corresponds to three sub-pixel areas 10, the length of the sub-scanning line GL1 is about 29.7×3=89.1 μm. Of course, one sub-scanning line GL1 may also correspond to five or more sub-pixel areas 10 as long as the length thereof does not exceed 6 mm. In an embodiment, among the transistors in the same row, every three transistors are connected to the same sub-scanning line GL1, and the length of the sub-scanning line GL1 is 90-200 μm. The length of the sub-scanning line GL1 may be different for different products.

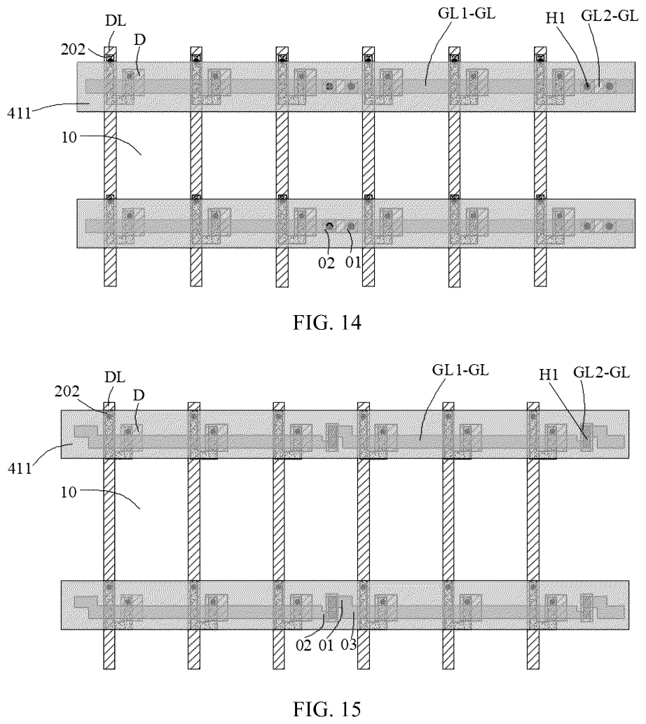

As shown in FIG. 13, FIG. 14, and FIG. 15, the present disclosure also provides a display panel including the array substrate as described in any of the above embodiments, and a color film substrate provided on a side of the array substrate. The color film substrate includes a color film layer 410, and the color film layer 410 includes a light-shielding portion 411 and a plurality of filtering portions 412 defined by the light-shielding portions 411. The filtering portions 412 are provided to respectively correspond to the sub-pixel areas 10 in a direction perpendicular to the base substrate 1. The color film substrate further includes a substrate 4, and the color film layer 410 is provided on a side of the substrate 4 close to the array substrate. The display panel further includes a liquid crystal layer 3 provided between the array substrate and the color film substrate. An orthographic projection, on the base substrate 1, of the connection line GL2 is located within an orthographic projection, on the base substrate 1, of the light-shielding portion 411 to avoid an influence on the aperture ratio of the display panel.

The display panel further includes a frame-sealing adhesive 32 sealed between the array substrate and the color film substrate. Further, the array substrate further includes a fifth conductive layer 215, a sixth conductive layer 216, and a first orientation layer 205, the fifth conductive layer 215 may include a first electrode 151, the sixth conductive layer 216 includes a second electrode 161, and the second electrode 161 is used to form an electric field with the first electrode 151 for driving the liquid crystal layer 3. The first electrode 151 may be a pixel electrode or a common electrode, and correspondingly, the second electrode 161 may be a common electrode or a pixel electrode. The first orientation layer 205 is provided between the sixth conductive layer 216 and the liquid crystal layer 3. An insulating layer is provided between respective conductive layers, and by way of example, the array substrate further includes a second planarization PLN2 and a passivation layer PVX, the second planarization layer PLN2 is provided between the second conductive layer 213 and the fifth conductive layer 215, and the passivation layer PVX is provided between the fifth conductive layer 2151 and the sixth conductive layer 216.

The color film substrate further includes a second orientation layer 420, the second orientation layer 420 is provided between the liquid crystal layer 3 and the color film layer 410. The display panel further includes a spacer 31 provided between the array substrate and the color film substrate, and an orthographic projection of the spacer 31 on the base substrate 1 is at least partially overlapped with an orthographic projection of the light-shielding portion 411 on the base substrate 1.

The present disclosure also provides a display device including the display module according to any embodiment of the present disclosure. The display device may be a vehicle-mounted product, a mobile phone, a tablet computer, a television, a monitor, a laptop computer, a digital photo frame, a navigator, and any other product or component having a display function.

It is to be understood that the application of the present disclosure is not limited to the detailed structure and arrangement of the components described in the specification. The present disclosure may have other implementations and can be realized and performed in a variety of ways. The foregoing modification and change fall within the scope of the present disclosure. It is to be understood that the present disclosure, as disclosed and limited in this specification, extends to all alternative combinations of two or more individual features mentioned or apparent in the description and/or the accompanying drawings. All of these various combinations constitute a plurality of alternative aspects of the present disclosure. The implementations in the specification illustrate the best manners known for implementing the present disclosure and will enable those skilled in the art to utilize the present disclosure.

1. An array substrate comprising a plurality of scanning lines and a plurality of data lines, wherein
the plurality of data lines are intersected with the plurality of scanning lines to define a plurality of sub-pixel areas;
the scanning line comprises a plurality of sub-scanning lines spaced apart from each other and a connection line connecting two adjacent sub-scanning lines; and
the array substrate further comprises a base substrate and a plurality of conductive layers provided on a side of the base substrate, and the sub-scanning line and the connection line are arranged in different conductive layers respectively.

2. The array substrate according to claim 1, wherein the array substrate further comprises a plurality of transistors, and
the plurality of conductive layers comprise:
a first conductive layer, provided on the side of the base substrate, and comprising a gate electrode of the transistor; and
a second conductive layer, provided on a side, away from the base substrate, of the first conductive layer, and comprising a source electrode and a drain electrode of the transistor,
wherein the sub-scanning line is arranged in the first conductive layer.

3. The array substrate according to claim 2, wherein the connection line is arranged in the second conductive layer.

4. The array substrate according to claim 2, wherein the plurality of conductive layers further comprise:
a third conductive layer, provided between the base substrate and the first conductive layer, and comprising a light-shielding structure,
wherein the connection line is arranged in the third conductive layer.

5. The array substrate according to claim 2, wherein the plurality of conductive layers further comprise:
a third conductive layer, provided between the base substrate and the first conductive layer, and comprising a light-shielding structure; and
a fourth conductive layer, provided on a side, close to the base substrate, of the third conductive layer, or between the third conductive layer and the first conductive layer, or between the first conductive layer and the second conductive layer, or on a side, away from the base substrate, of the second conductive layer,
wherein the connection line is arranged in the fourth conductive layer.

6. The array substrate according to claim 2, wherein the scanning line extends in a first direction, the sub-scanning lines are arranged in the first direction, the sub-scanning line has a head end and a tail end, and the tail end of a previous sub-scanning line is connected to the head end of a next the sub-scanning line by the connection line; and
an orthographic projection, on the base substrate, of the connection line connecting the two adjacent sub-scanning lines is at least partially overlapped with orthographic projections, on the base substrate, of the two adjacent sub-scanning lines.

7. The array substrate according to claim 6, wherein the two adjacent sub-scanning lines comprises a first sub-scanning line and a second scanning line, and the tail end of the first sub-scanning line is provided next to the head end of the second sub-scanning line in the first direction.

8. The array substrate according to claim 7, wherein an interval between the tail end of the first sub-scanning line and the head end of the second the sub-scanning line is not less than 3 μm.

9. The array substrate according to claim 8, wherein the array substrate further comprises an active layer, a first gate insulating layer and an interlayer dielectric layer, the active layer is provided between the base substrate and the first conductive layer, the first gate insulating layer is provided between the active layer and the first conductive layer, and the interlayer dielectric layer is provided between the first conductive layer and the second conductive layer;
the connection line is arranged in the second conductive layer, the interlayer dielectric layer is provided with a first through-hole passing through the interlayer dielectric layer, an orthographic projection, on the base substrate, of the first through-hole is at least partially overlapped with the orthographic projection, on the base substrate, of the sub-scanning line, and the orthographic projection, on the base substrate, of the first through-hole is at least partially overlapped with the orthographic projection, on the base substrate, of the connection line; and
the connection line is connected to the sub-scanning line through the first through-hole, and the first through-hole has an aperture of not less than 3 μm.

10. The array substrate according to claim 8, wherein the plurality of conductive layers further comprise a third conductive layer provided between the base substrate and the first conductive layer, and comprising a light-shielding structure,
the array substrate further comprises a buffer layer and a first gate insulating layer, and the buffer layer and the first gate insulating layer are stacked between the third conductive layer and the first conductive layer in a direction away from the base substrate;
the connection line is arranged in the third conductive layer, the buffer layer and the first gate insulating layer are provided with a first through-hole passing through the buffer layer and the first gate insulating layer an orthographic projection, on the base substrate, of the first through-hole is at least partially overlapped with the orthographic projection, on the base substrate, of the sub-scanning line, and the orthographic projection, on the base substrate, of the first through-hole is at least partially overlapped with the orthographic projection, on the base substrate, of the connection line; and
the connection line is connected to the sub-scanning line through the first through-hole, and the first through-hole has an aperture of not less than 3 μm.

11-13. (canceled)

14. The array substrate according to claim 9, wherein the first gate insulating layer and the interlayer dielectric layer are provided with a second through-hole passing through the first gate insulating layer and the interlayer dielectric layer, the source electrode and the drain electrode of the transistor in the second conductive layer are connected to the active layer through the second through-hole, and the second through-hole has an aperture of not less than 2.8 μm.

15. The array substrate according to claim 6, wherein the sub-scanning line further comprises an intermediate portion between the head end and the tail end; and
the two adjacent sub-scanning lines comprises a first sub-scanning line and a second sub-scanning line, the intermediate portion of the second sub-scanning line is provided at a side of the tail end of the first sub-scanning line in the first direction, and the head end of the second sub-scanning line is provided next to the tail end of the first sub-scanning line in a second direction, the second direction being perpendicular to the first direction.

16. The array substrate according to claim 15, wherein a first gap is provided between the two adjacent sub-scanning lines in the first direction, and the first gap has a dimension of not less than 2.4 μm in the first direction.

17. The array substrate according to claim 16, wherein the array substrate further comprises an active layer, a first gate insulating layer and an interlayer dielectric layer, the active layer is provided between the base substrate and the first conductive layer, the first gate insulating layer is provided between the active layer and the first conductive layer, and the interlayer dielectric layer is provided between the first conductive layer and the second conductive layer;
the connection line is arranged in the second conductive layer, the interlayer dielectric layer is provided with a first through-hole passing through the interlayer dielectric layer, an orthographic projection, on the base substrate, of the first through-hole is at least partially overlapped with the orthographic projection, on the base substrate, of the sub-scanning line; and
the connection line is connected to the sub-scanning line through the first through-hole, and the first through-hole has an aperture of not less than 3 μm.

18. The array substrate according to claim 16, wherein when the plurality of conductive layers further comprise the third conductive layer, the array substrate further comprises a buffer layer and a first gate insulating layer, and the buffer layer and the first gate insulating layer are stacked between the third conductive layer and the first conductive layer in a direction away from the base substrate;
the connection line is arranged in the third conductive layer, the buffer layer and the first gate insulating layer are provided with a first through-hole passing through the buffer layer and the first gate insulating layer, and an orthographic projection, on the base substrate, of the first through-hole is at least partially overlapped with the orthographic projection, on the base substrate, of the sub-scanning line; and
the connection line is connected to the sub-scanning line through the first through-hole, and the first through-hole has an aperture of not less than 3 μm.

19. The array substrate according to claim 17, wherein a second gap is provided between the tail end of the first sub-scanning line and the head end of the second sub-scanning line in the second direction.

20. The array substrate according to claim 18, wherein as for the two adjacent sub-scanning lines, a second gap is provided between the tail end of the first sub-scanning line and the head end of the second sub-scanning line in the second direction.

21. (canceled)

22. The array substrate according to claim 1, wherein the plurality of transistors are arranged to form rows along an extension direction of the scanning line, every three transistors in a same row of transistors are connected to a same sub-scanning line, and the sub-scanning line has a length of 90-200 μm.

23. The array substrate according to claim 1, wherein the connection line is located between transistors of two adjacent sub-pixel area arranged in an extension direction of the scanning line.

24. A display panel comprising:
the array substrate according to claim 1;
a color film substrate, provided on a side of the array substrate and comprising a color film layer, the color film layer comprising a light-shielding portion and a plurality of filtering portions defined by the light-shielding portion, and the filtering portions being provided to respectively correspond to the sub-pixel areas in a direction perpendicular to the base substrate; and
a liquid crystal layer, provided between the array substrate and the color film substrate,
wherein an orthographic projection, on the base substrate, of the connection line is located within an orthographic projection, on the base substrate, of the light-shielding portion.

25. (canceled)
